(19) United States
(12) Patent Application Publication
(10) Pub. No.: US 2026/0188385 A1
(43) Pub. Date: Jul. 2, 2026

(54) NAND FLASH MEMORY DEVICE AND OPERATING METHOD THEREOF

(71) Applicant: Samsung Electronics Co., Ltd., Suwon-si (KR)

(72) Inventors: Sijung YOO, Suwon-si (KR); Seunggeol NAM, Suwon-si (KR); Dukhyun CHOE, Suwon-si (KR)

(73) Assignee: Samsung Electronics Co., Ltd., Suwon-si (KR)

(21) Appl. No.: 19/246,340

(22) Filed: Jun. 23, 2025

(30) Foreign Application Priority Data
Dec. 27, 2024 (KR) 10-2024-0199330

(51) Int. Cl. G11C 16/04; G11C 16/10; H10B 41/20; H10D 30/69

(52) U.S. Cl. CPC G11C 16/0483; G11C 16/10; H10B 41/20; H10D 30/701

(57) ABSTRACT

Provided are a NAND flash memory device and an operating method thereof. According to the operating method of the NAND flash memory device, a maximum pass voltage, a minimum pass voltage, and a voltage drop width are set as Vpass, max, Vpass,min, and ΔV, respectively, and during a programming operation, a program voltage is applied to a selected word line, Vpass, max−(n−1)ΔV is applied to an unselected word line at an n-th (n is a natural number) position away from the selected word line as a pass voltage, and Vpass, min is applied to an unselected word line satisfying a condition of Vpass,max−(n−1)ΔV<Vpass,min as the pass voltage.

### CROSS-REFERENCE TO RELATED APPLICATION

This application is based on and claims priority under 35 U.S.C. § 119 to Korean Patent Application No. 10-2024-0199330, filed on Dec. 27, 2024, in the Korean Intellectual Property Office, the disclosure of which is incorporated by reference herein in its entirety.

### BACKGROUND

### 1. Field

The present disclosure relates to NAND flash memory devices and operating methods thereof.

### 2. Description of the Related Art

As hard disks according to the related art have been replaced with solid state drives (SSDs), NAND flash memory devices, that is, non-volatile memory devices, have been widely commercialized. In a NAND flash memory device, a memory cell includes one transistor, and information is recorded via fluctuation in a threshold voltage of the transistor.

Recently, research onto application of a ferroelectric field effect transistor (FeFET) to a NAND flash memory device has been conducted. An FeFET is a semiconductor device with memory characteristics implemented by adjusting a threshold voltage according to a polarization direction of a ferroelectric material by using the ferroelectric material as a gate insulating layer and has advantages of a low operating voltage, rapid programming speed, etc.

### SUMMARY

Some example embodiments of the present application provide NAND flash memory devices and operating methods thereof.

Additional aspects will be set forth in part in the description which follows and, in part, will be apparent from the description, or may be learned by practice of the presented example embodiments of the disclosure.

According to an example embodiment, an operating method of a NAND flash memory device including a plurality of strings each having a plurality of memory cells connected in series, the method may include setting a maximum pass voltage, a minimum pass voltage, and a voltage drop width as Vpass,max, Vpass,min, and ΔV,r espectively, and during a programming operation, applying a program voltage to a selected word line, applying Vpass,max31 (n−1)ΔV as a pass voltage to an unselected word line at an n-th (n is a natural number) position away from the selected word line, and applying Vpass,min as the pass voltage to the unselected word line satisfying a condition of Vpass,max−(n-1)ΔV<Vpass,min.

The setting may include determining Vpass,max, Vpass,min, and ΔV to ensure boosting of the channel potentials of the unselected strings.

The setting may include determining Vpass,max, Vpass,min, and ΔV to ensure which a difference between a maximum program voltage and a channel potential of each of the unselected strings is greater than a minimum program voltage.

A maximum threshold voltage of each memory cell may be 0 V or less.

Vpass,min may be 1 V or less.

Each memory cell may include a ferroelectric field-effect transistor (FeFET).

The FeFET may include a channel layer, a ferroelectric layer, and a gate electrode that are sequentially stacked.

The channel layer may include oxide semiconductor.

According to an example embodiments, a NAND flash memory device may include a plurality of strings each including a plurality of memory cells connected in series, wherein the NAND flash memory device is configured to set a maximum pass voltage, a minimum pass voltage, and a voltage drop width as Vpass,max, Vpass,min, and ΔV, respectively, and during a programming operation, apply a program voltage to a selected word line, apply Vpass,max−(n−1)ΔV to an unselected word line at an n-th (n is a natural number) position away from the selected word line as a pass voltage, and apply Vpass,min to the unselected word line satisfying a condition of Vpass,max−(n−1)ΔV<Vpass,min as the pass voltage.

The NAND flash memory device may be configured to determine Vpass,max, Vpass,min, and ΔV ensuring that a difference between a maximum program voltage and a channel potential of each of the unselected strings is greater than a minimum program voltage.

A maximum threshold voltage of each memory cell may be 0 V or less.

Vpass,min may be 1 V or less.

Each memory cell may include a FeFET.

The FeFET may include a channel layer including oxide semiconductor, a ferroelectric layer, and a gate electrode.

According to an example embodiment, a NAND flash memory device may include a plurality of strings each including a plurality of memory cells connected in series, wherein, during a programming operation, the NAND flash memory device is configured to apply a program voltage to a selected word line, apply varying pass voltages decreasing gradually away from the selected word line to first unselect word lines, and apply a constant pass voltage to second unselected word lines.

When a maximum pass voltage, a minimum pass voltage, and a voltage drop width are set as Vpass,max, Vpass,min, and ΔV, respectively, the NAND flash memory device may be configured to apply the varying pass voltages of Vpass,max (n−1)ΔV to the first unselected word lines that are at an n-th (n is a natural number) position away from the selected word line.

The constant pass voltage may be Vpass,min.

The NAND flash memory device may be configured to determine Vpass,max, Vpass,min, and ΔV, ensuring that a difference between a maximum program voltage and a channel potential of the unselected string is greater than a minimum program voltage so that the channel potential of the unselected string is boosted.

A maximum threshold voltage of each memory cell may be 0 V or less, and Vpass,min may be 1 V or less.

Each memory cell may include a FeFET, and the FeFET may include a channel layer including oxide semiconductor, a ferroelectric layer, and a gate electrode.

### BRIEF DESCRIPTION OF THE DRAWINGS

The above and other aspects, features, and advantages of certain example embodiments of the disclosure will be more apparent from the following description taken in conjunction with the accompanying drawings, in which:

FIG. 1 is a cross-sectional view schematically showing a ferroelectric field-effect transistor (FeFET) applicable to each memory cell in a NAND flash memory device, according to an example embodiment;

FIGS. 2A and 2B are diagrams showing on/off states of a channel according to a polarization direction of a ferroelectric layer in the FeFET of FIG. 1;

FIG. 3 is a diagram showing a gate voltage-drain current characteristic with respect to the FeFET of FIG. 1;

FIG. 4 is a perspective view showing an example of a NAND flash memory device, according to an example embodiment;

FIG. 5 is an equivalent circuit diagram of the NAND flash memory device of FIG. 4;

FIG. 6 is a diagram schematically illustrating an operating method of a NAND flash memory device according to a first comparative example;

FIG. 7 is a diagram schematically illustrating an operating method of a NAND flash memory device according to a second comparative example;

FIG. 8 is a diagram illustrating an operating method of the NAND flash memory device according to an example embodiment;

FIG. 9 is a diagram showing an example of a fluctuation in a threshold voltage according to a program voltage in a FeFET applied to a memory cell of a NAND flash memory device, according to an example embodiment;

FIG. 10 is a diagram showing an example of voltages applied to word lines according to the operating method of the NAND flash memory device according to an example embodiment by using the result of FIG. 9;

FIG. 11 is a diagram conceptually showing a device architecture applicable to an electronic device according to an example embodiment;

FIG. 12 is a block diagram of a memory system according to an example embodiment; and

FIG. 13 is a block diagram showing a neuromorphic device and an external device connected to the neuromorphic device according to an example embodiment.

### DETAILED DESCRIPTION

Reference will now be made in detail to example embodiments,

examples of which are illustrated in the accompanying drawings, wherein like reference numerals refer to like elements throughout. In this regard, the present example embodiments may have different forms and should not be construed as being limited to the descriptions set forth herein. Accordingly, the example embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Hereinafter, one or more example embodiments will be described in detail with reference to accompanying drawings. In the drawings, like reference numerals denote like components, and sizes of components in the drawings may be exaggerated for convenience of explanation. The example embodiments of the disclosure are capable of various modifications and may be embodied in many different forms.

When a layer, a film, a region, or a panel is referred to as being “on” another element, it may be directly on/under/at left/right sides of the other layer or substrate, or intervening layers may also be present. Singular forms include plural forms unless apparently indicated otherwise contextually. It will be further understood that when a portion is referred to as “comprising” another component, the portion may not exclude another component but may further comprise another component unless the context states otherwise.

The use of the term of “the above-described” and similar indicative terms may correspond to both the singular forms and the plural forms. Also, the steps of all methods described herein may be performed in any suitable order unless otherwise indicated herein or otherwise clearly contradicted by context.

Also, the terms “. . . unit”, “. . . module” used herein specify a unit for processing at least one function or operation, and this may be implemented with hardware or software or a combination of hardware and software.

Furthermore, the connecting lines or connectors shown in the drawings are intended to represent example functional relationships and/or physical or logical couplings between the various elements. It should be noted that many alternative or additional functional relationships, physical connections, or logical connections may be present in a practical device.

The use of any and all examples, or example language provided herein, is intended merely to better illuminate the disclosure and does not pose a limitation on the scope of the present disclosure unless otherwise claimed.

In a NAND flash memory device, a memory cell includes one transistor, and information is recorded via fluctuation in a threshold voltage of the transistor. A ferroelectric field-effect transistor (FeFET) is a semiconductor device implementing non-volatile memory characteristics by adjusting a threshold voltage according to a polarization direction of a ferroelectric material by using the ferroelectric material as a gate insulating layer. The FeFET may have a minimum threshold voltage and a maximum threshold voltage determined according to a polarization status of a ferroelectric material, and a difference between the minimum threshold voltage and the maximum threshold voltage may be a memory window (MW). The FeFET may be applied to a memory cell of the NAND flash memory device.

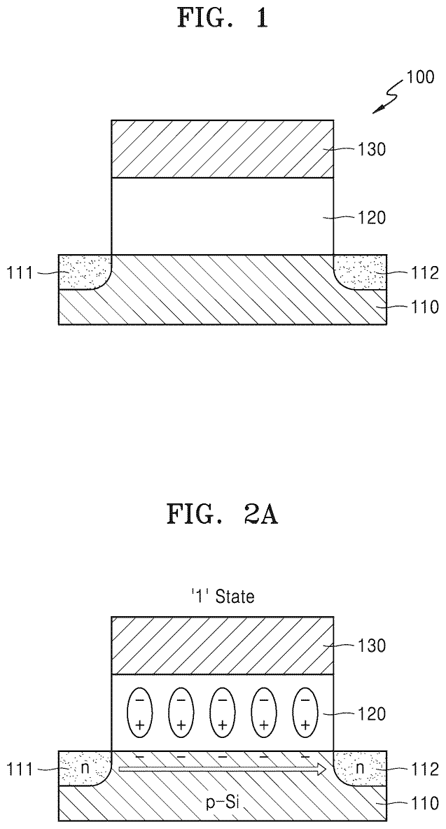

FIG. 1 is a cross-sectional view schematically showing a ferroelectric field-effect transistor (FeFET) 100 applicable to each memory cell in a NAND flash memory device, according to an example embodiment.

Referring to FIG. 1, the FeFET 100 includes a channel layer 110, a ferroelectric layer 120, and a gate electrode 130 that are stacked sequentially. The channel layer 110 may include a semiconductor material. For example, the channel layer 110 may include a group-IV semiconductor such as Si, Ge, SiGe, etc. or a group III-V semiconductor compound. The channel layer 110 may include, for example, a two-dimensional (2D) semiconductor material, quantum dot, or organic semiconductor. The 2D semiconductor material denotes a semiconductor material having a layered-structure in which element atoms are two-dimensionally bonded. The 2D semiconductor material may include, for example, a transition metal dechalcogenide (TMD) that is a compound of transition metal and chalcogen element. The channel layer 110 may further include a dopant. Here, the dopant may include a p-type dopant or an n-type dopant. A p-type dopant may include, for example, B, Al, Ga, In, etc., and an n-type dopant may include, for example, P, As, Sb, etc. In addition, the above-stated materials are merely examples.

The channel layer 110 may include, for example, an oxide semiconductor such as indium gallium zinc oxide (IGZO), a nitride semiconductor, or an oxynitride semiconductor. When the channel layer 110 includes an oxide semiconductor, a maximum threshold voltage of the FeFET 100 may be reduced to about 0 V or less.

A first doping region 111 and a second doping region 112 may be formed on opposite sides of the channel layer 110. The first doping region 111 may be, for example, a source region. The first doping region 111 may be a p or n-type doping region. The second doping region 112 may be, for example, a drain region. The second doping region 112 may be a p or n-type doping region.

The channel layer 110 may include a ferroelectric layer 120 including a ferroelectric material. The ferroelectric material is a material having ferroelectricity in which internal electric dipole moments are aligned to maintain spontaneous polarization. The ferroelectric material has a remnant polarization due to dipoles even in a state where an electric field is not applied from the outside. In the ferroelectric material, the direction of polarization may be switched on a domain basis by an external electric field.

The ferroelectric material may include, for example, a fluorite-based material, a nitride-based material, or perovskite-based material. The fluorite-based material may include, for example, at least one of hafnium oxide (HfO), zirconium oxide (ZrO), or hafnium-zirconium oxide (HfZrO). The nitride-based material may include, for example, AlScN, etc. The perovskite-based material may include one of lead zirconate titanate (PZT), strontium bismuth tantalate (SBT), or barium titanate (BTO). The ferroelectric layer 120 may further include a certain dopant. The dopant may include, for example, at least one of La, Y, Gd, Si, Al, Mg, Sr, or Ba. However, one or more example embodiments are not limited thereto.

An intermediate oxide layer (not shown) may be further provided between the channel layer 110 and the ferroelectric layer 120. The intermediate oxide layer may reduce or prevent movement of oxygen from the channel layer 110 to the ferroelectric layer 120. The intermediate oxide layer may include, for example, at least one of niobium oxide (Nb₂O₅), tantalum oxide (Ta₂O₅), or titanium oxide (TiO₂). However, one or more example embodiments are not limited thereto.

The gate electrode 130 is provided on the ferroelectric layer 120. The gate electrode 130 may include a conductive material. For example, the gate electrode 130 may include metal, metal nitride, metal oxide, polysilicon, etc. For example, the gate electrode 110 may include at least one of W, TiN, TaN, WN, NbN, Mo, Ru, Ir, RuO, IrO, or highly doped polysilicon. However, one or more example embodiments are not limited thereto. The gate electrode 130 may have a structure in which a plurality of materials are stacked. For example, the gate electrode 130 may have a stack structure of metal nitride layer/metal layer, such as TiN/W, etc. However, one or more example embodiments are not limited to the above examples.

A gate intermediate layer (not shown) may be further provided between the ferroelectric layer 120 and the gate electrode 130. The gate intermediate layer may be provided to reduce a capacitance between the ferroelectric layer 120 and the gate electrode 130 and increase the memory window MW. To this end, the gate intermediate layer may include a dielectric material having a relatively low dielectric constant. For example, the gate intermediate layer may include at least one of amorphous dielectric material from silicon oxide (SiO), silicon nitride (SiN), aluminum oxide (AlO), or silicon oxynitride (SiON).

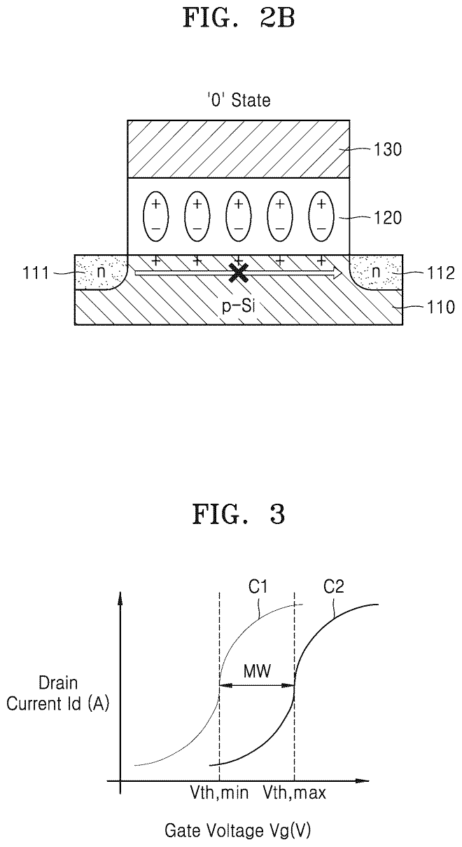

FIGS. 2A and 2B are diagrams showing on/off states of a channel according to a polarization direction of a ferroelectric layer 120 in the FeFET 100 of FIG. 1. FIGS. 2A and 2B show an example in which the channel layer 110 is formed of p-Si (e.g., silicon doped with p-type dopants), and the first and second doping regions 111 and 112 are formed as n-type doping regions.

When a first gate voltage is applied to the gate electrode 130, the ferroelectric layer 120 has a state having the polarization direction as shown in FIG. 2A, and accordingly, current flows in the channel layer 110 under the ferroelectric layer 120. In the channel-on state, for example, information of ‘1’ may be recorded on the memory cell. In addition, when a second gate voltage is applied to the gate electrode 130, the ferroelectric layer 120 is in a state having the polarization direction as shown in FIG. 2B, and accordingly, the current does not flow in the channel layer 110 under the ferroelectric layer 120. In the channel-off state, for example, information of ‘0’ may be recorded on the memory cell.

FIG. 3 is a diagram showing a gate voltage Vg-drain current Id characteristic with respect to the FeFET 100 of FIG. 1.

In FIG. 3, C1 denotes an example in which the ferroelectric layer 120 has the polarization state as shown in FIG. 2A, and C2 denotes an example in which the ferroelectric layer 120 has the polarization state as shown in FIG. 2B. As shown in FIG. 3, the FeFET 100 may implement the memory characteristics by changing the threshold voltage according to the polarization direction of the ferroelectric layer 120. The FeFET 100 may have a minimum threshold voltage Vth, min and a maximum threshold voltage Vth, max determined according to the polarization state of the ferroelectric layer 120, and a difference between the minimum threshold voltage Vth, min and the maximum threshold voltage Vth, max may correspond to the memory window MW.

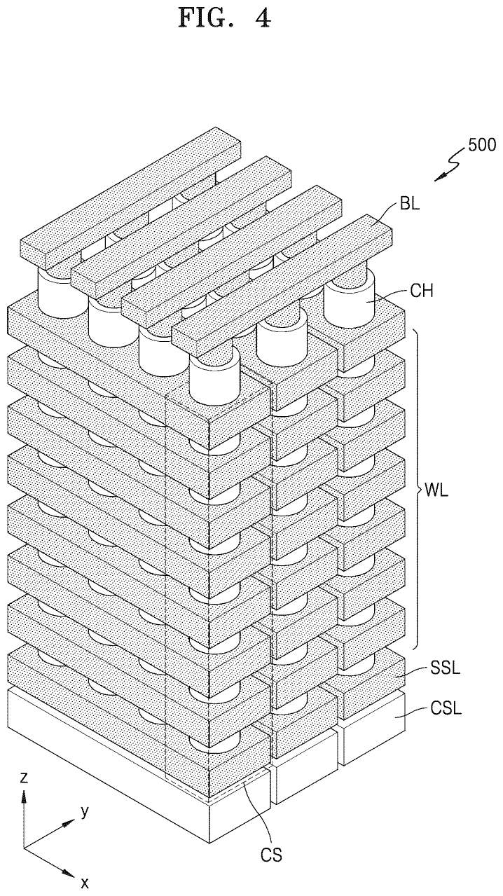

FIG. 4 is a perspective view showing an example of a NAND flash memory device 500, according to an example embodiment.

Referring to FIG. 4, the NAND flash memory device 500 includes strings CS arranged between bit lines BL and common source lines CSL. The strings CS may be arranged, for example, in an x-axis direction and a y-axis direction, and each of the strings CS may extend in a direction perpendicular to the substrate, for example, a z-axis direction.

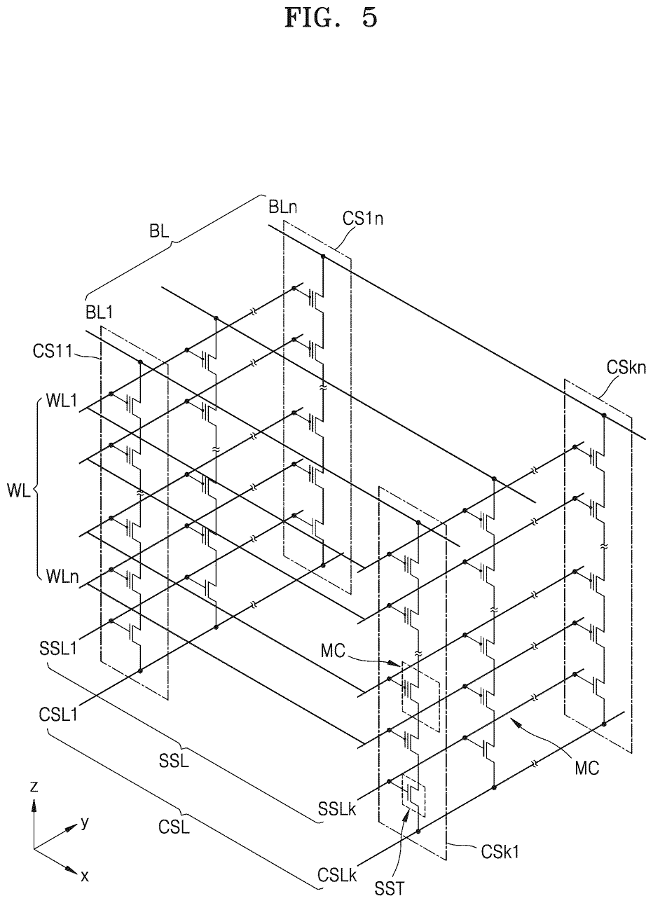

Each of the strings CS includes a plurality of memory cells (MC of FIG. 5) connected in series. The plurality of memory cells MC may each have the same structure as that of the FeFET 100 described above. Each of the memory cells MC may include a channel layer CH, a ferroelectric layer, and a gate electrode. Here, the channel layer CH may be shared by the plurality of memory cells MC included in each string CS. The channel layer CH may extend in a direction parallel to the string CS, that is, the z-axis direction. The channel layer CH, the ferroelectric layer, and the gate electrode are described above, and thus, detailed descriptions thereof are omitted.

In the strings CS, word lines WL arranged in the z-axis direction and the y-axis direction may be provided, and each of the word lines WL may extend in the x-axis direction. A certain word line WL may be electrically connected to the memory cells (e.g., gate electrodes) arranged in the x-axis direction. Bit lines BL arranged in the x-axis direction may be provided above the strings CS, and each of the bit lines BL may extend in the y-axis direction. String selection lines SSL may be provided in the y-axis direction in lower portions of the strings CS, and each of the string selection lines SSL may extend in the x-axis direction.

FIG. 5 is an equivalent circuit diagram of the NAND flash memory device 500 of FIG. 4.

Referring to FIG. 5, k×n strings CS may be provided on a substrate (not shown) in a matrix form, and may be each named as CSij (1≤i≤k, 1≤j≤n) according to a location thereof in each row and column. Each string CSij is connected to the bit line BL, the string selection line SSL, the word line WL, and the common source line CSL.

Each of the strings CSij includes memory cells MC and a string selection transistor SST. The memory cells MC and the string selection transistors SST in each of the strings CSij may be stacked in a direction perpendicular to the substrate, e.g., the z-axis direction.

The plurality of rows of the strings CS are connected to different string selection lines SSL1 to SSLk, respectively. For example, the string selection transistors SST in strings CS11 to CS1n are commonly connected to a string selection line SSL1. The string selection transistors SST in the strings CSk1 to CSkn are commonly connected to the string selection line SSLk. The plurality of columns of the strings CS are connected to different bit lines BL1 to BLn, respectively. For example, the memory cells MC and the string selection transistors SST in the strings CS11 to CSk1 may be commonly connected to the bit line BL1, and the memory cells MC and the string selection transistors SST in the strings CS1n to CSkn may be commonly connected to the bit line BLn.

The plurality of rows of the strings CS may be connected to different common source lines CSL1 to CSLk, respectively. For example, the string selection transistors SST in the strings CS11 to CS1n may be commonly connected to the common source line CSL1 and the string selection transistors SST of the strings CSk1 to CSkn may be commonly connected to the common source line CSLk. The memory cells MC at the same height from the string selection transistors SST are commonly connected to one word line WL and the memory cells MC at different heights from the string selection transistors SST may be connected to different word lines WL1 to WLm, respectively.

The circuit structure shown in FIG. 5 is an example. For example, the number of rows of the strings CS may be increased or decreased. As the number of rows of the strings CS varies, the number of string selection lines connected to the rows of the strings CS and the number of strings CS connected to one bit line BL may also vary. As the number of rows of the strings CS varies, the number of common source lines CSL connected to the rows of the strings CS may also vary.

The number of columns of the strings CS may be also increased or decreased. As the number of columns of the strings CS varies, the number of bit lines 150 connected to the columns of the cell strings CS and the number of strings CS connected to one string selection line SSL may also vary.

The height of the strings CS may increase or decrease. For example, the number of memory cells MC stacked in each of the strings CS may increase or decrease. As the number of memory cells MC stacked in each of the strings CS varies, the number of word lines WL may also vary. For example, the number of string selection transistors provided to each of the strings CS may increase. As the number of string selection transistors SST provided to each of the strings CS varies, the number of the string selection lines SSL or the common source lines CSL may also vary. As the number of string selection transistors SST increases, the string selection transistors SST may be stacked like the memory cells MC.

For example, writing and reading operations may be performed in units of rows of the strings CS. The strings CS are selected by the common source lines CSL in units of one row and may be selected by the string selection lines SSL in units of one row. Also, the voltage may be applied in units of at least two common source lines CSL. The voltage may be applied in units of total common source lines CSL.

In a selected row of the strings CS, the writing and reading operations may be performed in units of pages. A page may denote one row of memory cells MC connected to one word line WL. In the selected row of the strings CS, the memory cells MC may be selected by the word lines WL in units of pages.

For example, when a memory cell MC to be recorded on is selected, a gate voltage value of the corresponding memory cell MC is adjusted so as not to form a channel, that is, so that the channel is turned off, and gate voltage values of unselected memory cells MC are adjusted so that channels in the unselected memory cells MC are turned on. Accordingly, desired information (‘1’ or ‘0’) may be recorded on the selected memory cell MC due to a program voltage Vpgm applied between the common source line CSL and the bit line BL.

In a reading operation, reading of the selected memory cell MC may be performed similarly as above. That is, the gate voltages applied to the memory cells MC are adjusted so that the channel of the selected memory cell MC is turned off and the channels of the unselected memory cells MC are turned on, and after that, an electric current flowing in the corresponding memory cell MC due to an applied read voltage Vread between the common source line CSL and the bit line BL is measured to identify the information (‘1’ or ‘0’) of the memory cell MC.

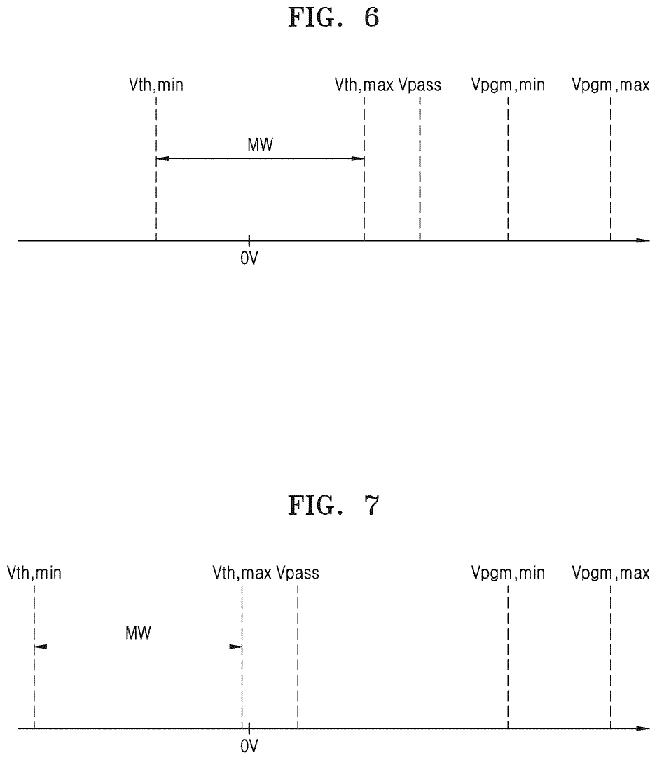

FIG. 6 is a diagram schematically illustrating a method of operating a NAND flash memory device according to a first comparative example. FIG. 6 shows an operating method for recording information on a certain memory cell when the memory cell of the NAND flash memory device has a maximum threshold voltage Vth, max of a relatively large positive value.

Referring to FIG. 6, the program voltage between a maximum program voltage Vpgm, max and a minimum program voltage Vpgm, min is applied to a certain memory cell to be programmed in the string selected for the programming operation. In addition, a pass voltage Vpass greater than the maximum threshold voltage Vth, max is applied to the other memory cells so that the other memory cells in the selected string may be all turned on. However, as shown in FIG. 6, when the memory cell has the maximum threshold voltage Vth, max of a relatively large positive value, the pass voltage Vpass greater than the maximum threshold voltage Vth, max has to be applied to the other memory cells in the selected string, and thus, a power consumption issue may occur.

FIG. 7 is a diagram schematically illustrating a method of operating a NAND flash memory device according to a second comparative example. FIG. 7 shows an operating method for recording information on a certain memory cell when the memory cell of the NAND flash memory device has a maximum threshold voltage Vth, max less than 0 V. As described above, the maximum threshold voltage Vth, max less than 0 V may be implemented by the FeFET having a channel layer formed of the oxide semiconductor.

Referring to FIG. 7, the program voltage between a maximum program voltage Vpgm, max and a minimum program voltage Vpgm, min is applied to a certain memory cell to be programmed in the string selected for the programming operation. In addition, a pass voltage Vpass greater than the maximum threshold voltage Vth, max is applied to the other memory cells so that the other memory cells in the selected string may be all turned on. As shown in FIG. 7, when the memory cell has the maximum threshold voltage Vth, max less than 0 V, the pass voltage Vpass having a value close to 0 V, e.g., of about 1 V or less, is applied to all of the other memory cells in the selected string, and thus, the power reduction issue may be addressed. However, when the pass voltage Vpass is close to 0 V, another issue may occur during the programming operation.

In general, in a NAND flash memory device, channel potentials of unselected strings increase close to the pass voltage due to self-boosting scheme, and accordingly, an undesired programming operation automatically performed on the memory cells existing between the unselected string and the selected word line may be reduced or prevented. Therefore, using of relatively high pass voltage is disadvantageous in terms of power consumption, but may be effective in reducing or preventing the undesired programming operation. However, as shown in FIG. 7, when a value close to 0 V is used as the pass voltage Vpass, the channel potential of the unselected string also approaches to 0 V, and thus, undesired programming operations may be performed on the memory cells existing between the unselected string and the selected word line.

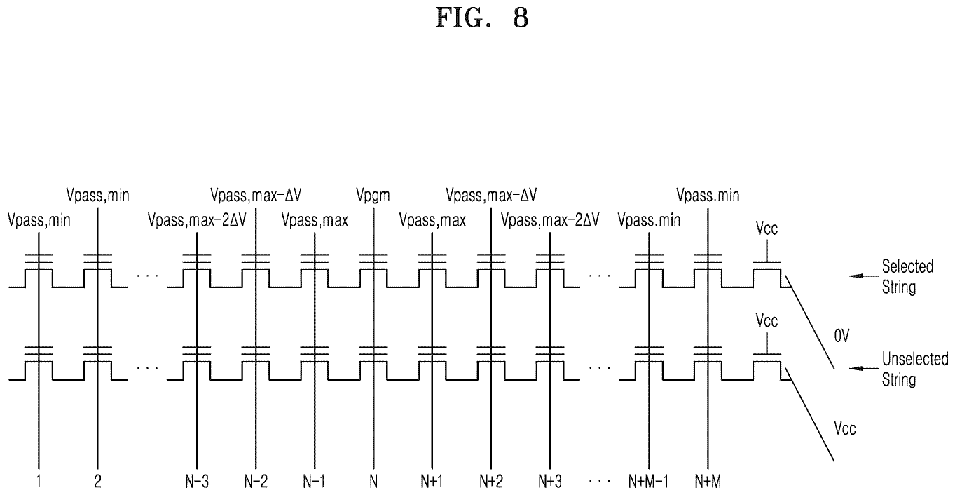

FIG. 8 is a diagram illustrating a method of operating the NAND flash memory device according to an example embodiment. FIG. 8 shows two strings, in particular, a selected string and unselected string, for convenience of description. Each memory cell in the NAND flash memory device may include the FeFET 100 of FIG. 1. Here, when oxide semiconductor is used as, for example, the channel layer, the maximum threshold voltage of about 0 V or less may be implemented.

Referring to FIG. 8, in order to perform the programming operation on a certain memory cell that is to be programmed in the selected string, a word line connected to the certain memory cell is selected, and a program voltage is applied to the selected word line. The program voltage may have a value ranging from the minimum program voltage Vpgm. min to the maximum program voltage Vpgm, max. Here, the maximum program voltage and the minimum program voltage may be determined from the variation characteristic of the threshold voltage according to the program voltage, as described later.

A pass voltage is applied to the word lines that are not selected. The pass voltage applied to the unselected word lines may be determined as follows.

The maximum pass voltage, the minimum pass voltage, and a voltage drop width are set as Vpass,max, Vpass,min, and ΔV. Here, Vpass,max, Vpass,min, and ΔV may be determined so that the channel potentials of the unselected strings may be boosted. For example, Vpass,max, Vpass,min, and ΔV may be determined so that a condition in which a difference between the maximum program voltage Vpgm, max and the channel potential of the unselected string is greater than the minimum program voltage Vpgm,min may be satisfied. Vpass,max, Vpass,min, and ΔV may be determined via various logics.

The pass voltage applied to the unselected word lines may be determined as follows. Vpass,max−(n−1)ΔV is applied to an unselected word line at an n-th (n is a natural number) position away from the selected word line as a pass voltage. In addition, a pass voltage Vpass,min is applied to the unselected word line corresponding to Vpass,max−(n−1)ΔV<Vpass,min.

In more detail, the pass voltage applied to the unselected word line that is closest to the selected word line, that is, the first unselected word line from the selected word line, may be the maximum pass voltage, that is, Vpass,max. In addition, the pass voltage applied to the second unselected word line from the selected word line may be Vpass,max−ΔV, and the pass voltage applied to a third unselected word line from the selected word line may be Vpass,max−2ΔV. In addition, the minimum pass voltage, that is, Vpass,min, is equally applied as a pass voltage to the unselected word lines that are k-th word lines from the selected word line and satisfy Vpass,max−(k−1)ΔV<Vpass,min.

FIG. 8 shows an example in which an N-th word line, from among N+M word lines, is selected for the programming operation. Referring to FIG. 8, the program voltage is applied to the N-th word line, that is, the selected word line. The maximum pass voltage, that is, Vpass,max, may be applied as the pass voltage to the unselected word lines that are closest to the N-th word line, that is, first word lines from the N-th word line, that is, (N+1)-th word line and the (N−1)-th word line. Vpass,max−ΔV may be applied as the pass voltage to second word lines from the N-th word line, that is, (N+2)-th word line and an (N−2)-th word line, respectively. Vpass,max−2ΔV may be applied as the pass voltage to third word lines from the N-th word line, that is, (N+3)-th word line and an (N−3)-th word line, respectively. In addition, the minimum pass voltage, that is, Vpass,min, is equally applied as a pass voltage to the unselected word lines that are k-th word lines from the selected word line and satisfy Vpass,max−(k−1)ΔV<Vpass,min, for example, first, second, (N+M−1)-th, and (N+M)-th word lines.

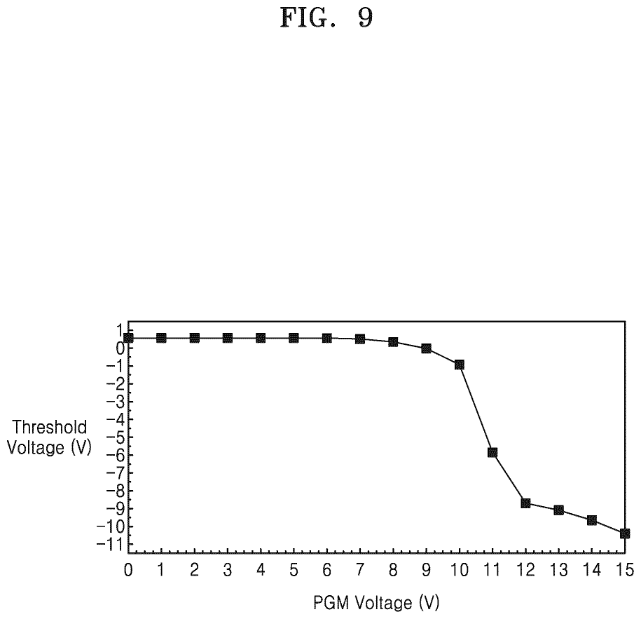

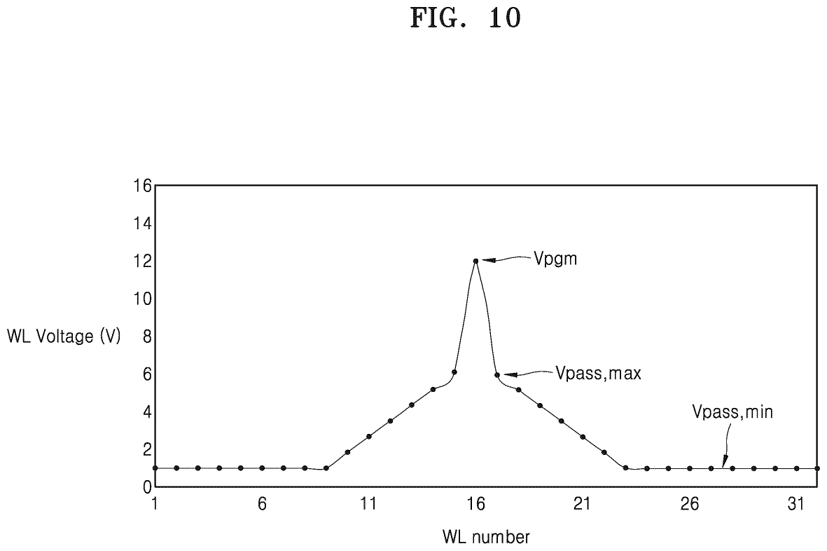

Hereinafter, detailed examples of the method of operating the NAND flash memory device according to an example embodiment are described below with reference to FIGS. 9 and 10.

FIG. 9 is a diagram showing an example of a fluctuation in a threshold voltage according to a programming voltage in an FeFET applied to a memory cell of a NAND flash memory device. Here, the FeFET uses, for example, oxide semiconductor, as a channel layer. FIG. 10 is a diagram showing an example of voltages applied to word lines according to the method of operating the NAND flash memory device according to an example embodiment, by using the result of FIG. 9.

From the result shown in FIG. 9, the maximum threshold voltage Vth,max is about 0 V or less. Also, the minimum program voltage Vpgm,min and the maximum program voltage Vpgm,max may be determined as 8 V and 12 V, respectively. In this case, under the condition in which the channel potential of the unselected string is less than 4 V, the maximum pass voltage, the minimum pass voltage, and the voltage drop width may be respectively set as Vpass,max, Vpass,min, and ΔV.

Vpass,min set as the minimum pass voltage may be the voltage around the maximum threshold voltage Vth,max, e.g., 1 V. In addition, Vpass,max set as the maximum pass voltage may be determined as 6 V that is less than the minimum program voltage Vpg,min.

FIG. 10 shows, when a program voltage is applied to a sixteenth word line during the programming operation on 32 word lines, pass voltages applied to the other word lines. Here, Vpass,max set as the maximum pass voltage and Vpass,min set as the minimum pass voltage are set as 6 V and 1 V, and the voltage drop width ΔV is 0.83 V.

Referring to FIG. 10, the program voltage of 12 V is applied to the sixteenth word line that is the selected word line. In addition, a pass voltage of Vpass,max−(n−1)ΔV is applied to unselected word lines at n-th (n is a natural number) positions away from the sixteenth word line, and Vpass,min is applied to unselected word lines corresponding to a condition of Vpass,max−(n−1)ΔV<Vpass,min.

Referring to FIG. 10, the pass voltage of 6 V that is Vpass,max is applied to each of fifteenth and seventeenth word lines that are word lines at first positions away from the sixteenth word line. In addition, the pass voltage of 5.17 V is applied to fourteenth and eighteenth word lines that are at second positions away from the sixteenth word line, and the pass voltage of 4.34 V is applied to thirteenth and nineteenth word lines that are at third positions away from the sixteenth word line. The pass voltage of 3.51 V is applied to twelfth and twentieth word lines that are at fourth positions away from the sixteenth word line, and the pass voltage of 2.68 V is applied to eleventh and twenty-first word lines that are at fifth positions away from the sixteenth word line. The pass voltage of 1.85 V is applied to tenth and twenty-second word lines that are at sixth positions away from the sixteenth word line, and the pass voltage of 1.02 V is applied to ninth and twenty-third word lines that are at seventh positions away from the sixteenth word line. In addition, the pass voltage Vpass,min, that is, 1 V, is constantly applied to first to eighth and twenty-fourth to thirty-second word lines that are at eighth or greater positions away from the sixteenth word line. As described above, the pass voltage that is gradually decreased from 6 V is applied to unselected word lines in the direction away from the sixteenth word line, that is, the selected word line, and then, the pass voltage of 1 V may be constantly applied to the word lines at eighth or greater positions away from the sixteenth word line.

In the example embodiment, the pass voltage applied to the unselected word lines is decreased from Vpass,max away from the selected word line, and then, may be constantly maintained at Vpass,min. Therefore, when the maximum threshold voltage of the memory cell is about 0 V or less, a value of Vpass,min may be set as a value closer thereto, for example, about 1 V or less, and thus, the power consumption may be reduced. Also, because the relatively high pass voltage is only applied to some memory cells in the vicinity of the memory cell that is to be programmed, undesired programming operation performed on the unselected memory cells may be reduced or prevented.

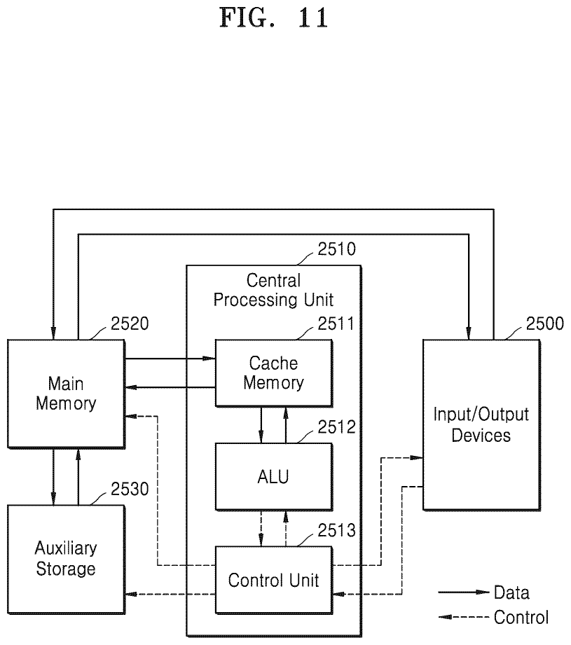

The NAND flash memory device described above may be applied to various electronic devices. FIG. 11 is a conceptual diagram schematically showing device architectures applied to an electronic apparatus, according to an example embodiment.

Referring to FIG. 11, a cache memory 2511, an ALU 2512, and a control unit 2513 may configure a central processing unit 2510, and the cache memory 2511 may include a static random access memory (SRAM). Separately from the CPU 2510, a main memory 2520 and an auxiliary storage 2530 may be provided. Also, an input/output element 2500 may be further provided. Each of the main memory 2520 and the auxiliary storage 2530 may include the NAND flash memory device operating in the manner according to the above-described example embodiments. In some cases, a device architecture may be implemented in a form in which computing unit devices and memory unit devices are adjacent to each other in one chip, without distinction of sub-units. The NAND flash memory devices that operate according to the above-described example embodiments may be implemented as a chip-type memory block to be used as a neuromorphic computing platform or used to construct a neural network.

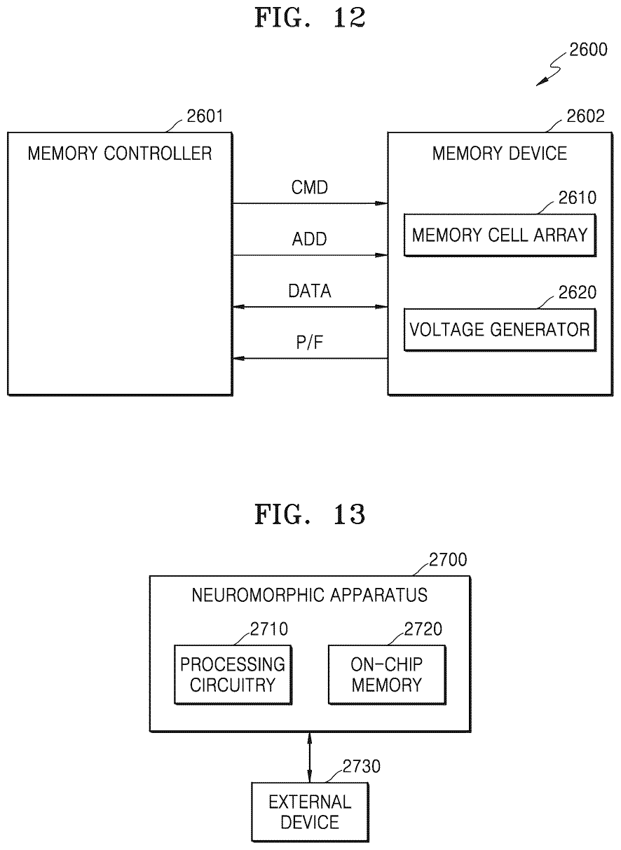

FIG. 12 is a block diagram of a memory system 2600 according to an example embodiment.

Referring to FIG. 12, the memory system 2600 may include a memory controller 2601 and a memory device 2602. The memory controller 2601 performs a control operation on the memory device 2602, for example, the memory controller 2601 may provide the memory device 2602 with a command CMD for performing a programming (or recording), reading, and/or erasing operation on an address ADD and the memory device 2602. Also, data for the programming operation and read data may be transferred between the memory controller 2601 and the memory device 2602. The memory device 2602 may include a memory cell array 2610 and a voltage generator 2620. The memory cell array 2610 may include a plurality of memory cells and may include the NAND flash memory device operating according to an embodiment.

The memory controller 2601 may include a processing circuit such as hardware including a logic circuit, a combination of hardware/software such as processor executed software, or a combination thereof. For example, the processing circuit may include, in particular, a central processing unit (CPU), an arithmetic logic unit (ALU), a digital signal processor, a micro-computer, a field programmable gate array (FPGA), a system-on-chip (SoC), a programmable logic unit, a micro-processor, an application-specific integrated circuit (ASIC), etc., but is not limited thereto. The memory controller 2601 may operate in response to a request from a host (not shown) and may access the memory device 2602 to control the control operation (e.g., recording/reading operation) discussed as above, and thus, the memory controller 2601 may be converted into a special purpose controller. The memory controller 2601 may generate an address ADD and a command CMD for performing programming/reading/erasing operations on the memory cell array 2610. Also, in response to the command from the memory controller 2601, the voltage generator 2620 (e.g., power circuit) may generate a voltage control signal for controlling a voltage level of a word line in order to perform data programming or data reading on the memory cell array 2610.

Also, the memory controller 2601 may perform a determination operation with respect to the data read from the memory device 2602. For example, from the data read from the memory cell, the number of on-cells and/or the number of off-cells may be determined. The memory device 2602 may provide the memory controller 2601 with a pass/fail signal (P/F) according to the determination result with respect to the read data. The memory controller 2601 may control the writing/reading operation of the memory cell array 2610 with reference to the pass/fail signal (P/F).

FIG. 13 is a block diagram showing a neuromorphic device 2700 and an external device 2730 connected to the neuromorphic device according to an example embodiment.

Referring to FIG. 13, the neuromorphic device 2700 may include a processing circuitry 2710 and/or an on-chip memory 2720. The neuromorphic device 2700 may include the NAND flash memory device operating in the manner according to the above-described example embodiment. In some example embodiments, the processing circuitry 2710 may be configured to control functions for driving the neuromorphic device 2700. For example, the processing circuitry 2710 may be configured to control the neuromorphic device 2700 by executing a program stored in the on-chip memory 2720. In some example embodiments, the processing circuitry 2710 may include hardware such as a logic circuit, hardware/software combination such as a processor executing software, or a combination thereof. For example, the processor may include, but is not limited to, a CPU, a graphic processing unit (GPU), an application processor (AP) included in the neuromorphic device 2700, an ALU, a digital signal processor, a micro-computer, a FPGA, an SoC, a programmable logic unit, a micro-processor, an ASIC, etc. In some example embodiments, the processing circuitry 2710 may be configured to read/record various data with respect to an external device 2730 and/or to execute the neuromorphic device 2700 by using the read/recorded data. In some example embodiments, the external device 2730 may include an external memory and/or sensor array having an image sensor (e.g., CMOS image sensor circuit).

In some example embodiments, the neuromorphic device 2700 of FIG. 13 may be applied to a machine learning system. The machine learning system may include various artificial neural network organizations and processing models, such as a convolution neural network (CNN), a repeated neural network (RNN) selectively including a deconvolution neural network, a long short-term memory (LSTM) unit, and/or a gated recurrent unit (GRU), a stacked neural network (SNN), a state-space dynamic neural network (SSDNN), a deep faith network (DBN), a generative adversarial network (GAN), and/or a restricted Boltzmann machine (RBM).

Alternatively or additionally, such machine learning systems may include other types of machine learning models, for example, linear and/or logistic regression, statistics clustering, Bayesian classification, determination trees, dimensional reduction such as main component analyses, expert systems, and/or random forests; or a combination thereof. The machine learning models may be used to provide various services and/or applications. For example, an image classification service, a user authentication service based on biometric information or biometric data, an advanced driver assistance system (ADAS) service, a voice assistance service, an automatic speech recognition (ASR) service, etc. may be executed by an electronic device. Although the example embodiments described above have been described above, these are merely examples, and various modifications may be made therefrom by those of ordinary skill in the art.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that some example embodiments described herein should be considered in a descriptive sense only and not for purposes of limitation. Descriptions of features or aspects within each example embodiment should typically be considered as available for other similar features or aspects in other example embodiments. While one or more example embodiments have been described with reference to the figures, it will be understood by those of ordinary skill in the art that various changes in form and details may be made therein without departing from the spirit and scope as defined by the following claims.

What is claimed is:

1. An operating method of a NAND flash memory device including a plurality of strings each having a plurality of memory cells connected in series, the method comprising:
setting a maximum pass voltage, a minimum pass voltage, and a voltage drop width as Vpass,max, Vpass,min, and ΔV, respectively; and
during a programming operation,
applying a program voltage to a selected word line,
applying Vpass,max−(n−1)ΔV as a pass voltage to an unselected word line at an n-th (n is a natural number) position away from the selected word line, and
applying Vpass,min as the pass voltage to the unselected word line satisfying a condition of Vpass,max−(n−1)ΔV<Vpass,min.

2. The method of claim 1, wherein
the setting comprises determining Vpass,max, Vpass,min, and ΔV to ensure boosting of channel potentials of unselected strings.

3. The method of claim 2, wherein
the setting comprises determining Vpass,max, Vpass,min, and ΔV to ensure that a difference between a maximum program voltage and a channel potential of each of the unselected strings is greater than a minimum program voltage.

4. The method of claim 1, wherein a maximum threshold voltage of each memory cell is 0 V or less.

5. The method of claim 4, wherein
Vpass,min is 1 V or less.

6. The method of claim 1, wherein
each of the plurality of memory cells includes a ferroelectric field-effect transistor (FeFET).

7. The method of claim 6, wherein
the FeFET comprises a channel layer, a ferroelectric layer, and a gate electrode.

8. The method of claim 7, wherein
the channel layer includes oxide semiconductor.

9. A NAND flash memory device comprising
a plurality of strings each including a plurality of memory cells connected in series,
wherein the NAND flash memory device is configured to
set a maximum pass voltage, a minimum pass voltage, and a voltage drop width as Vpass,max, Vpass,min, and ΔV, respectively, and
during a programming operation,
apply a program voltage to a selected word line,
apply Vpass,max−(n−1)ΔV to a first unselected word line at an n-th (n is a natural number) position away from the selected word line as a pass voltage, and
apply Vpass,min to a second unselected word line satisfying a condition of Vpass,max−(n−1)ΔV<Vpass,min as the pass voltage.

10. The NAND flash memory device of claim 9, wherein
the NAND flash memory device is configured to determine Vpass,max, Vpass,min, and ΔV, ensuring that a difference between a maximum program voltage and a channel potential of an unselected string is greater than a minimum program voltage.

11. The NAND flash memory device of claim 9, wherein
a maximum threshold voltage of each memory cell is 0 V or less.

12. The NAND flash memory device of claim 11, wherein
Vpass,min is 1 V or less.

13. The NAND flash memory device of claim 9, wherein
each of the plurality of memory cells includes a ferroelectric field-effect transistor (FeFET).

14. The NAND flash memory device of claim 13, wherein
the FeFET comprises a channel layer including oxide semiconductor, a ferroelectric layer, and a gate electrode.

15. A NAND flash memory device comprising
a plurality of strings each including a plurality of memory cells connected in series,
wherein, during a programming operation, the NAND flash memory device is configured to
apply a program voltage to a selected word line, and
apply varying pass voltages decreasing gradually away from the selected word line to first unselected word lines, and
apply a constant pass voltage to second unselected word lines.

16. The NAND flash memory device of claim 15, wherein,
when a maximum pass voltage, a minimum pass voltage, and a voltage drop width are set as Vpass,max, Vpass,min, and ΔV, respectively,
the NAND flash memory device is configured to apply the varying pass voltages of Vpass,max−(n−1)ΔV to the first unselected word lines that are at an n-th (n is a natural number) position away from the selected word line.

17. The NAND flash memory device of claim 16, wherein the constant pass voltage is Vpass,min.

18. The NAND flash memory device of claim 17, wherein
the NAND flash memory device is configured to determine Vpass,max, Vpass,min, and ΔV, ensuring that a difference between a maximum program voltage and a channel potential of an unselected string from among the plurality of strings is greater than a minimum program voltage.

19. The NAND flash memory device of claim 16, wherein
a maximum threshold voltage of each memory cell is 0 V or less, and Vpass,min is 1 V or less.

20. The NAND flash memory device of claim 16, wherein
each of the plurality of memory cells includes a ferroelectric field-effect transistor (FeFET), and
the FeFET comprises a channel layer including oxide semiconductor, a ferroelectric layer, and a gate electrode.
